(19) United States
(12) Patent Application Publication
(10) Pub. No.: US 2010/0052056 A1
(43) Pub. Date: Mar. 4, 2010

(54) ELECTROSTATIC DISCHARGE PROTECTION DEVICE

(76) Inventors: Yen-Wei Liao, Miaoli County (TW); Sheng-Yuan Yang, Taipei County (TW); Cheng-Yu Fang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/273,530

(22) Filed: Nov. 18, 2008

(30) Foreign Application Priority Data
Aug. 29, 2008 (TW) 097133202

(51) Int. Cl. H01L 29/78

(52) U.S. Cl. 257/355; 257/E29.255

(57) ABSTRACT

An ESD protection device includes a substrate with a doped well of a first conductive type, a first and a second doping region of the first conductive type and a third and a fourth doping region of a second conductive type respectively disposed in the doped well, a first gate disposed on the substrate and between the first and the second doping region, and a second gate disposed on the substrate and between the second and the third doping region to determine the distance between the second and the third doping region in order to precisely adjust the breakdown voltage of the ESD protection device of the present invention.

### BACKGROUND OF THE INVENTION

1. Field of the Invention

The present invention relates to an electrostatic discharge protection device (ESD). In particular, the present invention relates to an electrostatic discharge protection device used to precisely adjust the breakdown voltage.

2. Description of the Prior Art

Electrostatic discharge (ESD) is a major factor responsible for the damage of electrical overstress (EOS) of most electronic elements or electronic systems. The damaged electronic elements or electronic systems may be either temporarily disabled or permanently destroyed. This kind of unexpected electrical overstress destruction results in the damage of the electronic elements, adversely influencing the integrated circuits (IC) and making the electronic products fail to function.

The causes of the electrostatic discharge may come from various reasons and are usually inevitable. Static charges may accumulate in human bodies, devices, storages equipments during the manufacture, assembly, testing, storage of the electronic elements or electronic systems, even the electronic elements themselves may accumulate static charges. Static charges discharge when objects contact one another and damage takes its toll.

The object to equip the integrated circuits with the electrostatic discharge protection circuit is to protect the integrated circuits from the damage of the electrostatic discharge. The CMOS technique dominates the current semiconductor circuits. The electrostatic discharge may harm the delicate semiconductor chips in many ways. For example, the discharged charges punch through the thin gate insulator inside the elements or harm MOSFET and CMOS. Accordingly, if the integrated circuits are equipped with the electrostatic discharge protection circuit, they may function normally in the presence of the electrostatic discharge. On the contrary, the integrated circuits without the electrostatic discharge protection circuit may not function well in the presence of the electrostatic discharge. Even further, the chip may be partially disabled or potentially destroyed without obvious signs.

There are some known electrostatic discharge protection circuits. The first one is called a thin oxide device. FIG. 1 illustrates the conventional thin oxide device. The thin oxide device employs the parasitic NPN bipolar junction transistor (BJT) to protect the core circuit. Although the thin oxide device is more sensitive due to lower triggering voltage, the thin oxide device has lower tolerance to the high voltage discharge because the triggered electrostatic discharge current path is close to the surface of the Si substrate and thermal breakdown happens easily.

The second one is called a field oxide device. FIG. 2 illustrates the conventional field oxide device. The field oxide device also employs the parasitic NPN bipolar junction transistor (BJT) to protect the core circuit. The field oxide device keeps the triggered electrostatic discharge current path away from the surface of the Si substrate because field oxide is much thicker. However, the field oxide device is much less sensitive than the thin oxide device and cannot protect the interior circuit well.

The third one is called a modified electrostatic discharge protection device. Taiwan Patent publication 200731498 discloses a modified ESD protective circuit. FIG. 3 illustrates the conventional improved thin oxide device. The improved thin oxide device inherits the advantages of the thin oxide device. The distance D₁ between the N+ doping region 1 and the P+ doping region 2 is used to make the large current of the breakdown of the diode raise the voltage of the substrate and activate the parasitic NPN bipolar junction transistor (BJT) to release the destructive energy to protect the core circuit.

The fourth is called an improved field oxide device. FIG. 4 illustrates the conventional improved field oxide device. The improved field oxide device inherits the advantages of the field oxide device. The distance D₂ between the N+ doping region 3 and the P+ doping region 4 is used to make the large current of the breakdown of the diode raise the voltage of the substrate and activate the parasitic NPN bipolar junction transistor (BJT) to release the destructive energy to protect the core circuit.

No matter whichever of the thin oxide device or the field oxide device is used, the distance D between the N+ doping region and the P+ doping region is required to be precisely adjusted to control the breakdown of the diode. However, the location of the N+ doping region and of the P+ doping region is usually defined by the pattern of a regular lithographic photo mask. Nevertheless, the regular lithographic techniques are not accurate enough to precisely control the distance D between the N+ doping region and the P+ doping region and to indirectly obtain the expected space. The misalignment between the N+ doping region and the P+ doping region would lead to incomplete breakdown or complete no breakdown of the electrostatic discharge protection device under an expected voltage, which makes the electrostatic discharge protection device fail to be expectedly effective.

Therefore, a novel electrostatic discharge protection device is needed to not only go with the current metal-oxide-semiconductor process but also have precise breakdown voltage to cope with the electrostatic discharge. Such electrostatic discharge protection device should be evenly turned on, have smaller triggering voltage and a satisfying electrostatic discharge protection.

### SUMMARY OF THE INVENTION

Accordingly, the present invention proposes a novel electrostatic discharge protection device with a precise breakdown voltage to cope with the electrostatic discharge and to obtain a satisfying electrostatic discharge protection.

The electrostatic discharge protection device of the present invention includes a substrate with a doped well of a first conductive type, a first doping region and a second doping region of the first conductive type respectively disposed in the doped well and a third and a fourth doping region of a second conductive type respectively disposed in the doped well, a first gate disposed on the substrate and between the first doping region and the second doping region, and a second gate disposed on the substrate and between the second doping region and the third doping region to determine the distance between the second and the third doping region in order to precisely adjust the breakdown voltage of the electrostatic discharge protection device (ESD) of the present invention.

An expected width is obtained because the width is determined by a gate-defining procedure. In such a way, the novel electrostatic discharge protection device of the present invention is not only compatible with the current metal-oxide-semiconductor process, but also has precise breakdown voltage to cope with the electrostatic discharge. Such electrostatic discharge protection device can be evenly turned on, have smaller triggering voltage and a satisfying electrostatic discharge protection.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the conventional thin oxide device.

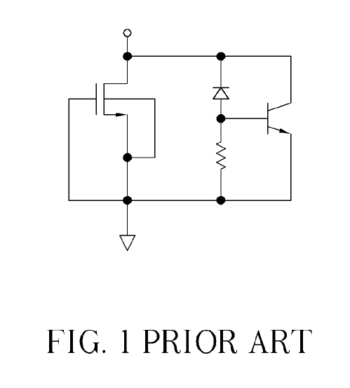

FIG. 2 illustrates the conventional field oxide device.

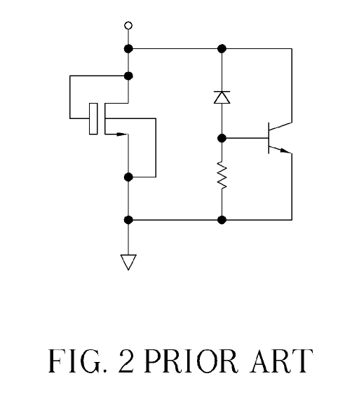

FIG. 3 illustrates the conventional improved thin oxide device.

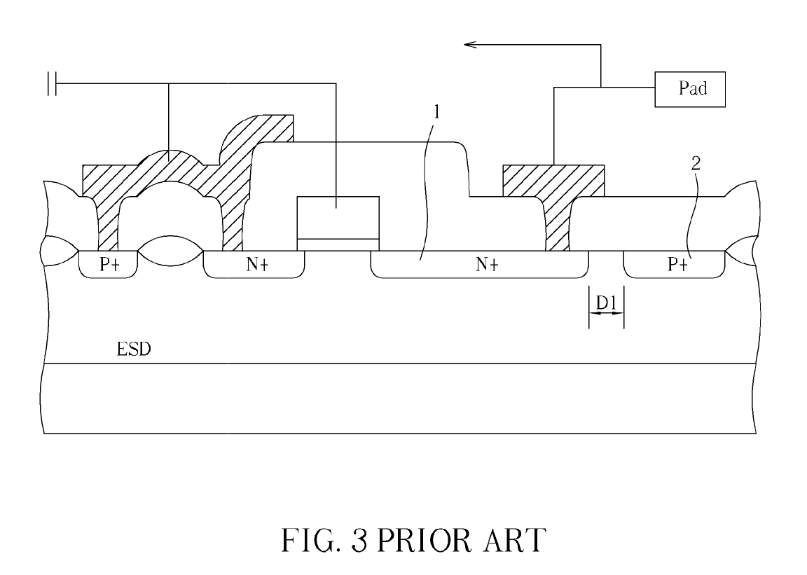

FIG. 4 illustrates the conventional improved field oxide device.

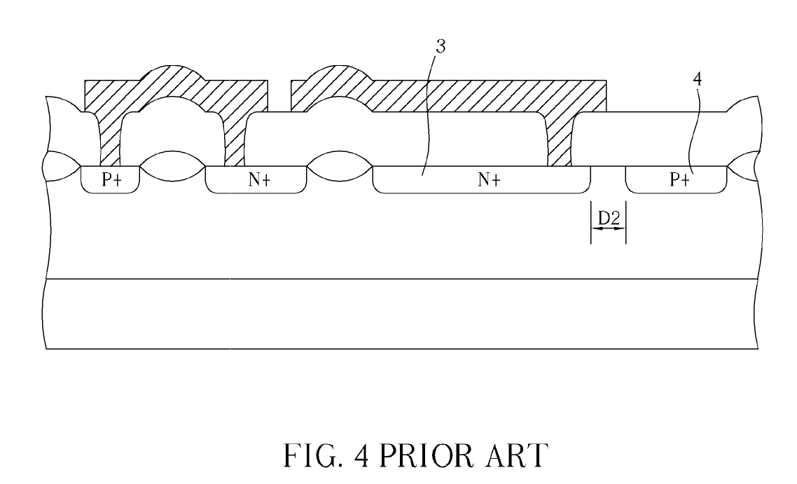

FIG. 5 illustrates a preferred example of the electrostatic discharge protection device of the present invention.

FIG. 6 illustrates another preferred example of the electrostatic discharge protection device of the present invention.

FIG. 7 illustrates the equivalent circuit diagram of the novel electrostatic discharge protection device of the present invention.

### DETAILED DESCRIPTION

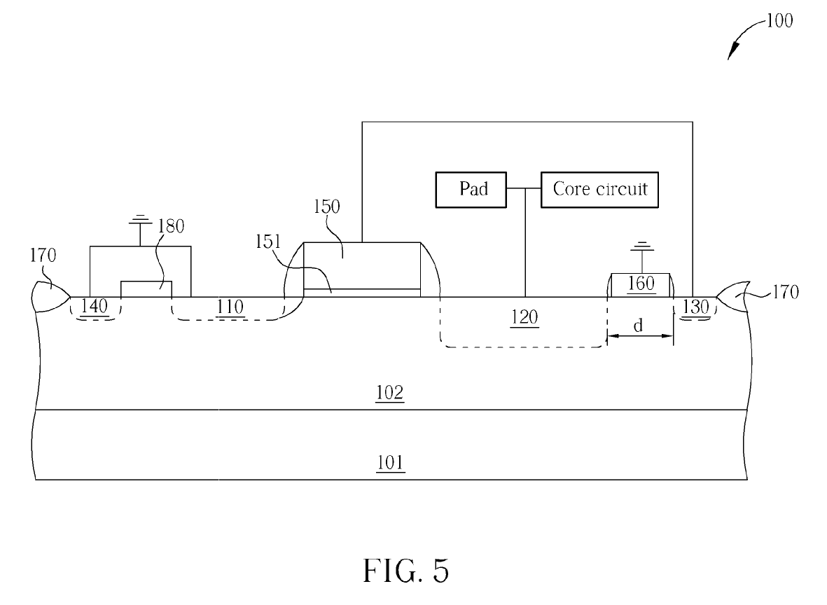

The present invention provides a novel electrostatic discharge protection device with precise breakdown voltage for use in electrostatic discharge protection and to protect the electronic elements in the integrated circuits. FIG. 5 illustrates a preferred example of the electrostatic discharge protection device of the present invention. As shown in FIG. 5, the electrostatic discharge protection device 100 of the present invention includes a substrate 101, a first doping region 110, a second doping region 120, a third doping region 130, a fourth doping region 140, a first gate 150 and a second gate 160.

The substrate 101 is usually a semiconductor substrate, such as Si, with a doped well 102 of a first conductivity type. The elements of the electrostatic discharge protection device 100 of the present invention are disposed in the doped well 102. As shown in FIG. 5, the electrostatic discharge protection device 100 of the present invention includes a first doping region 110, a second doping region 120, a third doping region 130, and a fourth doping region 140 respectively disposed in the doped well 102. The first doping region 110 and the second doping region 120 are of a first conductivity type, and the third doping region 130 and the fourth doping region 140 are of a second conductivity type. Preferably, the first conductivity type may be N type and the second conductivity type may be P type. In addition, there is an isolation oxide layer 170, such as a shallow trench isolation (STI) or a field oxide (FOX), surrounding as a whole to be an electric isolation. The methods to form the shallow trench isolation (STI) or the field oxide (FOX) are well known to persons of ordinary skills in the art and the details will not be discussed here.

The first gate 150 and the second gate 160 are disposed on the substrate 101. The first gate 150 is disposed between the first doping region 110 and the second doping region 120, and the second gate 160 is disposed between the second doping region 120 and the third doping region 130. The first gate 150 and the second gate 160 may be formed by conventional lithographic and etching methods.

Please note that the second gate 160 is disposed between the second doping region 120 and the third doping region 130 to determine a distance “d” between the second doping region 120 and the third doping region 130 so that the breakdown voltage of the electrostatic discharge protection device 100 of the present invention can be precisely adjusted. Generally speaking, the larger the distance “d” is, the greater the breakdown voltage is. The needed breakdown voltage is therefore easily obtained by controlling the size of the second gate 160.

Usually, the lithography technique to define the gate in a semiconductor process possesses the highest standard and precision of all. In other words, if the lithography technique to define the gate is also conveniently employed to define the distance of given doping regions, the obtained distance of the given doping regions enjoy the highest standard and precision of the same quality. In the presence of a secured and stable distance “d,” the electrostatic discharge protection device 100 of the present invention as a result may establish a precise breakdown voltage to deal with the electrostatic discharge.

On the other hand, because the second gate 160 is disposed between and above the second doping region 120 and the third doping region 130, the second gate 160 along with the photoresist mask for ions doping of the first conductivity type and of the second conductivity type may also serve as the doping mask for forming ion implantation of the second doping region 120 and the third doping region 130, thereby reinforcing the second doping region 120 and the third doping region 130 to be exactly in the pre-determined spots

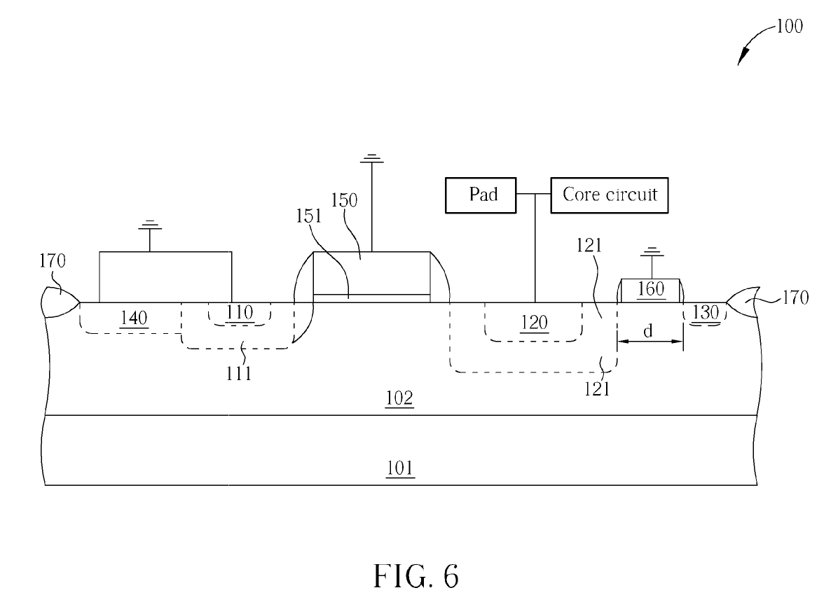

Supposing the electrostatic discharge protection device 100 of the present invention is required to sustain a higher voltage, optionally the drain and the source of the first gate 150, i.e. the first doping region 110 and the second doping region 120, may be further enclosed within another doping region of the same conductivity but of lower doping concentration, to form a structure of double diffused drain (DDD). FIG. 6 illustrates another preferred example of the electrostatic discharge protection device of the present invention. As shown in FIG. 6, a fifth doping region 111 is disposed in the doped well 102 and enclosing the first doping region 110. Similarly, a sixth doping region 121 is disposed in the doped well 102 and enclosing the second doping region 120.

In one preferred embodiment of the present invention, the isolation layer 151 of the first gate 150 may have different thickness. For example, if the isolation layer 151 of the first gate 150 is a general gate oxide layer, it may be considered as an electrostatic discharge protection device of thin oxide layer, as shown in FIG. 5. Such electrostatic discharge protection device has a relatively lower triggering potential and for this reason is more sensitive to the electrostatic discharge of lower voltage. Or alternatively, if the isolation layer 151 of the first gate 150 is a field oxide layer of higher thickness, it may be considered as an electrostatic discharge protection device of field oxide layer, as shown in FIG. 6. Although such electrostatic discharge protection device has a relatively higher triggering potential, for the same reason it is more durable to the electrostatic discharge of higher voltage. However, whatever the thickness of the isolation layer 151 of the first gate 150 is, it merely changes the operational voltage of the first gate 150 rather than changes the overall performance of the electrostatic discharge protection device 100 of the present invention.

Each element in the electrostatic discharge protection device 100 of the present invention may have different states of electrical connection. For instance, the first doping region 110 and the fourth doping region 140 are respectively grounded, or the second gate 160 is floating or grounded. The third doping region 130 and the first gate 150 may be electrically connected. When the third doping region 130 and the first gate 150 may be electrically connected, the large current which is caused by breakdown plus the voltage drop caused by the intrinsic electrical resistance of the substrate 101 raise the voltage of the first gate 150. In addition, when the third doping region 130 and the first gate 150 may be electrically connected, the electrostatic discharge current is provided with another extra dissipating route other than the parasitic NPN to help the electrostatic discharge protection device 100 of the present invention and to enhance the electrostatic discharge protection performance of the electrostatic discharge protection device 100 of the present invention, which are some of the features of the electrostatic discharge protection device 100 of the present invention. Besides, if a proper voltage is applied on the first gate 150, it may further enhance the electrostatic discharge protection of the electrostatic discharge protection device 100 of the present invention. Or alternatively, the third doping region 130 may be floating and the first gate 150 be grounded.

The second doping region 120 is electrically connected to an input output pad (I/O pad) and to a core circuit to protect the various elements in the core circuit from the destructive damage of the electrostatic discharge, as shown in FIG. 5. If the isolation layer 151 of the first gate 150 is a field oxide layer of higher thickness, as shown in FIG. 6, to float the first gate 150 is another embodiment of the present invention.

In still another embodiment of the present invention, the first doping region 110 and the fourth doping region 140 may be adjacent to each other or segregated from each other. As shown in FIG. 5, the electrically isolated first doping region 110 and the electrically isolated fourth doping region 140 are segregated from each other by an isolation layer 180. Optionally, the isolation layer 180 may include a shallow trench isolation or a field oxide layer. Or alternatively, as shown in FIG. 6, the first doping region 110 and the fourth doping region 140 are adjacent to each other.

As described and illustrated earlier, the present invention controls the control gate 160 through changing the conventional and original element structure and layout to enjoy the highest precision to have an exact gate width to precisely adjust the distance “d” between the second doping region 120 and the third doping region 130 by taking the advantage of the highest standard and precision of the lithography technique of the semiconductor process. Hence, the manufacturing process of the novel electrostatic discharge protection device of the present invention is surely compatible with the current metal-oxide-semiconductor (MOS) process.

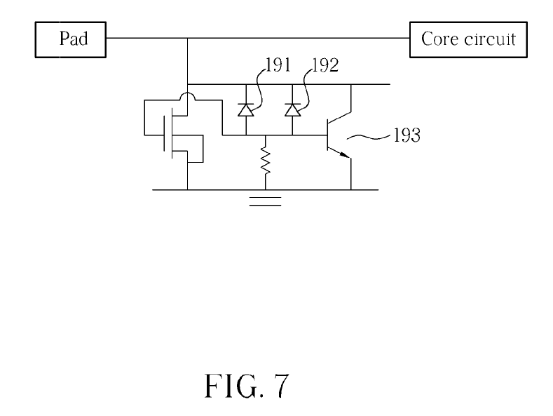

FIG. 7 illustrates the equivalent circuit diagram of the novel electrostatic discharge protection device of the present invention. By precisely controlling the distance “d” between the second doping region 120 and the third doping region 130, the breakdown voltage of the diode 192 in the diodes 191/192 is ensured. The large current of the breakdown of the diode 192 is used to raise the voltage of the substrate and to activate the parasitic NPN bipolar junction transistor (BJT) to release the destructive energy to protect the core circuit.

Those skilled in the art will readily observe that numerous modifications and alterations of the device and method may be made while retaining the teachings of the invention.

What is claimed is:

1. An electrostatic discharge protection device (ESD), comprising:
a substrate with a doped well of a first conductive type;
a first doping region and a second doping region of said first conductive type respectively disposed in said doped well;
a third doping region and a fourth doping region of a second conductive type respectively disposed in said doped well;
a first gate disposed on said substrate and between said first doping region and said second doping region; and
a second gate disposed on said substrate and between said second doping region and said third doping region, to determine a distance between said second doping region and said third doping region in order to precisely adjust a breakdown voltage of said electrostatic discharge protection device.

2. The electrostatic discharge protection device of claim 1, wherein said substrate is of said first conductive type.

3. The electrostatic discharge protection device of claim 1, wherein said first doping region is grounded.

4. The electrostatic discharge protection device of claim 1, wherein said fourth doping region is grounded.

5. The electrostatic discharge protection device of claim 1, wherein said third doping region and said first gate is electrically connected.

6. The electrostatic discharge protection device of claim 1, wherein said second gate is grounded.

7. The electrostatic discharge protection device of claim 1, further comprising:
a fifth doping region of said first conductive type disposed in said doped well and surrounding said first doping region.

8. The electrostatic discharge protection device of claim 1, further comprising:
a sixth doping region of said first conductive type disposed in said doped well and surrounding said second doping region.

9. The electrostatic discharge protection device of claim 1, wherein said first gate comprises a gate oxide layer.

10. The electrostatic discharge protection device of claim 1, wherein said first gate comprises a field oxide layer.

11. The electrostatic discharge protection device of claim 1, wherein said first doping region is adjacent to said fourth doping region.

12. The electrostatic discharge protection device of claim 1, further comprising:
an insulating layer, disposed between said first doping region and said fourth doping region to segregate said first doping region and said fourth doping region.

13. The electrostatic discharge protection device of claim 12, wherein said insulating layer comprises a shallow trench isolation.

14. The electrostatic discharge protection device of claim 12, wherein said insulating layer comprises a field oxide layer.

15. The electrostatic discharge protection device of claim 1, wherein said first conductive type is N type and said second conductive type is P type.

16. The electrostatic discharge protection device of claim 1, wherein said second doping region is electrically connected to a pad and a core circuit.
